(19) United States
(12) Patent Application Publication
(10) Pub. No.: US 2026/0129991 A1
(43) Pub. Date: May 7, 2026

(54) PHOTODETECTION DEVICE AND ELECTRONIC DEVICE

(71) Applicant: SONY SEMICONDUCTOR SOLUTIONS CORPORATION, KANAGAWA (JP)

(72) Inventor: TOMOHIRO YAMAZAKI, KANAGAWA (JP)

(21) Appl. No.: 19/118,352

(22) PCT Filed: Aug. 21, 2023
(86) PCT No.: PCT/JP2023/030034

§ 371 Date: Apr. 3, 2025

(30) Foreign Application Priority Data
Oct. 11, 2022 (JP) 2022-163350

(51) Int. Cl. H10F 39/00; G02B 5/20; G02B 5/30

(52) U.S. Cl. CPC H10F 39/806; H10F 39/8057; G02B 5/20; G02B 5/3058

(57) ABSTRACT

Provided is a photodetection device capable of suppressing generation of defective pixels. Specifically, the photodetection device includes a semiconductor substrate on which a plurality of photoelectric conversion units is formed; and a plurality of optical filters disposed on a light incident surface side of the semiconductor substrate. Furthermore, each of the optical filters includes a metal structure including a metal material of the same kind. Moreover, the photodetection device includes, between the metal structures, a slit portion spatially sectioning the metal structures.

### TECHNICAL FIELD

The present disclosure relates to a photodetection device and an electronic device.

### BACKGROUND ART

Conventionally, there has been proposed a photodetection device including a plurality of optical filters, each of the optical filters including a plurality of polarizers (for example, wire grid polarizer (WGP)) including a metal material (see, for example, Patent Document 1). In the photodetection device described in Patent Document 1, a lattice-shaped frame is formed between polarizers for the purpose of suppressing crosstalk and connecting layouts.

### CITATION LIST

### Patent Document

Patent Document 1: Japanese Patent Application Laid-Open No. 2019-179783

### SUMMARY OF THE INVENTION

### Problems to be Solved by the Invention

Generally, a metal material has a property that metal atoms move so that stress is relaxed. In a process of manufacturing a photodetection device, films having various intrinsic stresses are used, and thermal stress is generated by applying heat of several hundred degrees and then returning the temperature to room temperature, so that stress is applied to polarizers including a metal material. Therefore, in the polarizers, the metal atoms are moved to relax the stress. In addition, minute voids exist in the metal material. Therefore, in the polarizers, voids also move along with movement of the metal atoms.

Here, in the photodetection device described in Patent Document 1, all the polarizers are integrated by a frame. Therefore, when considering the movement of the voids in the photodetection device described in Patent Document 1, the metal atoms can freely move in all the polarizers, so that voids in the metal material are likely to grow, and thus there is a possibility that large voids are formed in the polarizers. That is, in the photodetection device described in Patent Literature 1, there is a possibility that metal atoms move to relax the stress, and a phenomenon in which voids grow in the polarizers and disconnection (stress migration) may occur. Then, as large voids are formed in the polarizers, the sensitivity value of the pixel having the polarizer in which large voids are formed increases, and a defective pixel (for example, a point defect) may be generated.

An object of the present disclosure is to provide a photodetection device and an electronic device capable of suppressing generation of a defective pixel.

### Solutions to Problems

A photodetection device of the present disclosure includes: (a) a semiconductor substrate on which a plurality of photoelectric conversion units is formed; and (b) a plurality of optical filters disposed on a light incident surface side of the semiconductor substrate, in which (c) each of the optical filters includes a metal structure including a metal material of a same kind, and (d) the photodetection device includes, between the metal structures, a slit portion spatially sectioning the metal structures.

An electronic device of the present disclosure includes a photodetection device including: (a) a semiconductor substrate on which a plurality of photoelectric conversion units is formed; and (b) a plurality of optical filters disposed on a light incident surface side of the semiconductor substrate, in which (c) each of the optical filters includes a metal structure including a metal material of a same kind, and (d) the photodetection device includes, between the metal structures, a slit portion spatially sectioning the metal structures.

### BRIEF DESCRIPTION OF DRAWINGS

FIG. 1 is a diagram illustrating an overall configuration of a solid-state imaging device according to a first embodiment.

FIG. 2 is a view illustrating a cross-sectional configuration of the solid-state imaging device taken along line A-A in FIG. 1.

FIG. 3 is a view illustrating a cross-sectional configuration of a light-shielding film taken along line B-B in FIG. 2.

FIG. 4 is a view illustrating a cross-sectional configuration of wire grid polarizers taken along line C-C in FIG. 2.

FIG. 5 is a view illustrating a cross-sectional configuration of the wire grid polarizers in a range wider than that in FIG. 4.

FIG. 6 is a view illustrating a cross-sectional configuration of the wire grid polarizers.

FIG. 7 is a view illustrating a cross-sectional configuration of a solid-state imaging device according to a modification.

FIG. 8 is a view illustrating a cross-sectional configuration of wire grid polarizers taken along line D-D in FIG. 7.

FIG. 9 is a view illustrating a cross-sectional configuration of a solid-state imaging device according to a modification.

FIG. 10 is a view illustrating a cross-sectional configuration of a GMR filter taken along line E-E in FIG. 9.

FIG. 11 is a view illustrating a cross-sectional configuration of a solid-state imaging device according to a modification.

FIG. 12 is a view illustrating a cross-sectional configuration of an FP filter taken along line F-F in FIG. 11.

FIG. 13 is a view illustrating a cross-sectional configuration of an optical filter array.

FIG. 14 is a view illustrating a cross-sectional configuration of an optical filter array.

FIG. 15 is a view illustrating a cross-sectional configuration of an optical filter array.

FIG. 16 is a view illustrating a cross-sectional configuration of an optical filter.

FIG. 17 is a view illustrating a cross-sectional configuration of an optical filter.

FIG. 18 is a view illustrating a cross-sectional configuration of an optical filter.

FIG. 19 is a view illustrating a cross-sectional configuration of a solid-state imaging device according to a modification.

FIG. 20 is a view illustrating a cross-sectional configuration of the optical filter taken along line G-G in FIG. 19.

FIG. 21 is a diagram illustrating a cross-sectional configuration of a solid-state imaging device according to a second embodiment.

FIG. 22 is a view illustrating a cross-sectional configuration of the solid-state imaging device taken along line H-H in FIG. 21.

FIG. 23 is a view illustrating a cross-sectional configuration of the solid-state imaging device taken along line I-I in FIG. 21.

FIG. 24 is a view illustrating a cross-sectional configuration of a solid-state imaging device according to a modification.

FIG. 25 is a view illustrating a cross-sectional configuration of the solid-state imaging device taken along line J-J in FIG. 24.

FIG. 26 is a view illustrating a cross-sectional configuration of a solid-state imaging device according to a modification.

FIG. 27 is a view illustrating a cross-sectional configuration of the solid-state imaging device taken along line K-K in FIG. 26.

FIG. 28 is a diagram illustrating an overall configuration of an electronic device according to a third embodiment.

### MODE FOR CARRYING OUT THE INVENTION

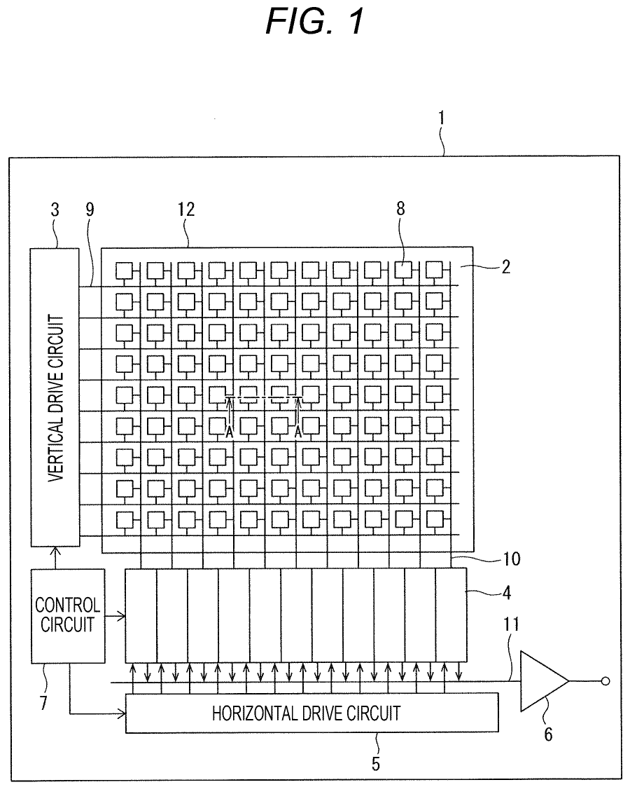

Hereinafter, examples of a photodetection device and an electronic device according to embodiments of the present disclosure will be described with reference to FIGS. 1 to 28. The embodiments of the present disclosure will be described in the following order. Note that the present disclosure is not limited to the following examples. Furthermore, the effects described in the present specification are illustrative and not restrictive, and there may be additional effects.

1. First Embodiment: Solid-State Imaging Device

1-1 Overall Configuration of Solid-State Imaging Device

1-2 Configuration of Main Part

1-3 Modifications

2. Second Embodiment: Solid-State Imaging Device

2-1 Configuration of Main Part

2-2 Modifications

3. Third Embodiment: Example of Application to Electronic Device

### 1. FIRST EMBODIMENT

### [1-1 Overall Configuration of Solid-State Imaging Device]

A solid-state imaging device 1 (in a broad sense, a “photodetection device”) according to a first embodiment of the present disclosure will be described. FIG. 1 is a diagram illustrating an overall configuration of the solid-state imaging device 1 according to the first embodiment.

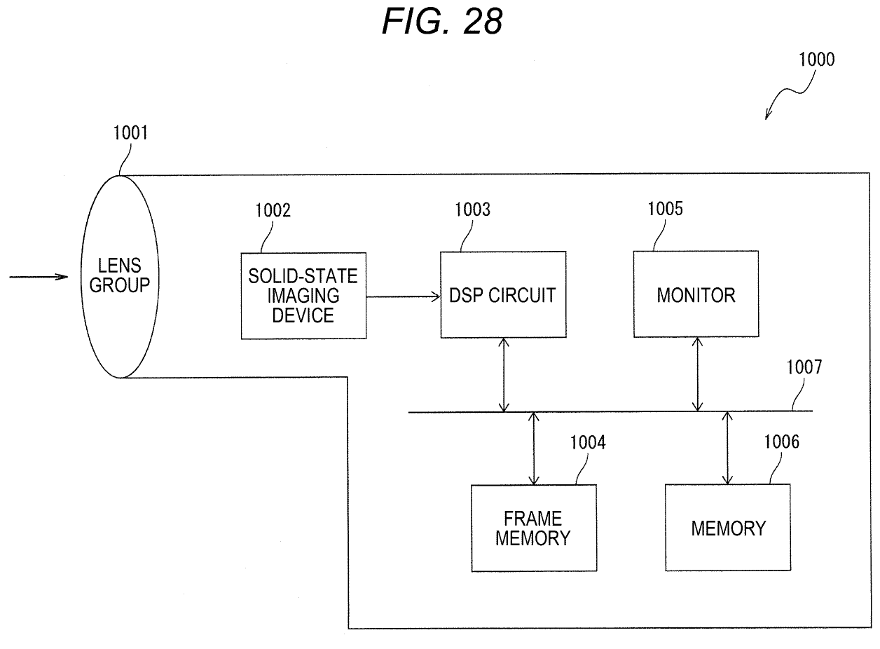

The solid-state imaging device 1 in FIG. 1 is a back-illuminated complementary metal oxide semiconductor (CMOS) image sensor. As illustrated in FIG. 28, the solid-state imaging device 1 (1002) captures image light (incident light) from a subject via a lens group 1001, converts an amount of the incident light an image of which is formed on an imaging surface into an electric signal in units of pixels, and outputs the electric signal as a pixel signal.

As illustrated in FIG. 1, the solid-state imaging device 1 includes a pixel region 2, a vertical drive circuit 3, column signal processing circuits 4, a horizontal drive circuit 5, an output circuit 6, and a control circuit 7.

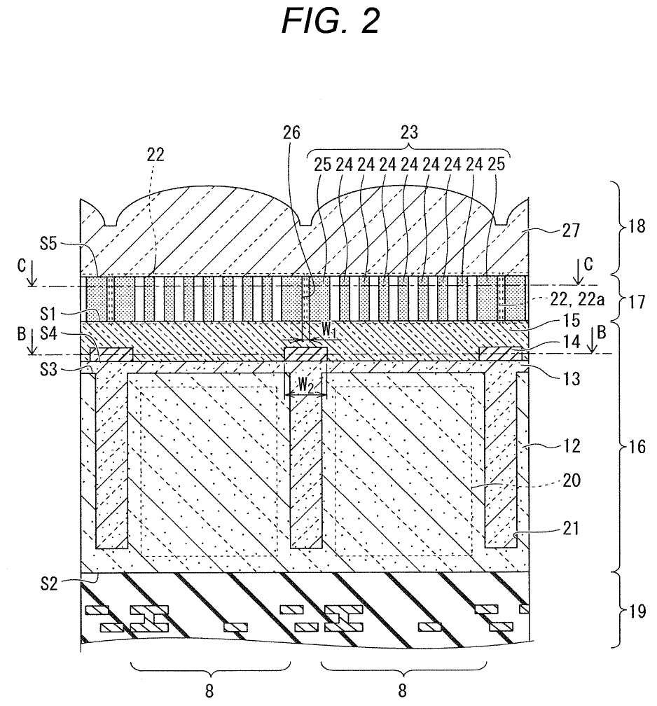

The pixel region 2 includes a plurality of the pixels 8 arranged in a two-dimensional array. The pixels 8 each include the photoelectric conversion unit 20 illustrated in FIG. 2 and a plurality of pixel transistors (for example, a transfer transistor, a reset transistor, an amplification transistor, and a selection transistor).

The vertical drive circuit 3 includes, for example, a shift register, sequentially selects the pixels 8 in the pixel region 2 row by row by, for example, sequentially outputting a selection pulse to pixel drive wirings 9, and outputs pixel signals of the selected pixels 8 to the column signal processing circuits 14 through vertical signal lines 10. Here, the pixel signal is a signal obtained by the charge generated by the photoelectric conversion unit 27 of each pixel 8.

The column signal processing circuits 4 are provided, for example, for the respective columns of the pixels 8, and perform signal processing on pixel signals output from the pixels 8 of one row for the respective pixel columns. As the signal processing, for example, correlated double sampling (CDS) for removing pixel-specific fixed pattern noise and analog digital (AD) conversion can be employed.

The horizontal drive circuit 5 includes, for example, a shift register, sequentially selects the column signal processing circuits 4 by sequentially outputting a horizontal drive pulse to the column signal processing circuits 4, and causes the selected column signal processing circuit 4 to output pixel signals subjected to the signal processing to a horizontal signal line 11.

The output circuit 6 performs signal processing on the pixel signals sequentially output from the column signal processing circuits 4 through the horizontal signal line 11, and outputs the pixel signals. As the signal processing, various types of digital signal processing such as buffering, black level adjustment, or column variation correction, for example, can be used.

The control circuit 7 generates a control signal and a clock signal as a reference for operations of the vertical drive circuit 3, the column signal processing circuits 4, the horizontal drive circuit 5, and the like, on the basis of a vertical synchronization signal, a horizontal synchronization signal, and a master clock signal. Then, the control circuit 7 outputs the generated clock signal and the control signal to the vertical drive circuit 3, the column signal processing circuits 4, the horizontal drive circuit 5, and the like.

### [1-2 Configuration of Main Part]

Next, a detailed structure of the solid-state imaging device 1 is described. FIG. 2 is a view illustrating a cross-sectional configuration of the solid-state imaging device 1 taken along line A-A in FIG. 1.

As illustrated in FIG. 2, in the solid-state imaging device 1, a light-receiving layer 16 is provided in which a semiconductor substrate 12, an insulating film 13, a light-shielding film 14, and a planarizing film 15 are stacked in this order. Furthermore, on a surface (hereinafter, also referred to as a “back surface S1”) of the light-receiving layer 16 on the planarizing film 15 side, an optical filter array 17 and a microlens array 18 are stacked in this order. Moreover, a wiring layer 19 is provided on a surface (hereinafter, also referred to as a “front surface S2”) on the semiconductor substrate 12 side of the light-receiving layer 16.

The semiconductor substrate 12 includes, for example, a silicon (Si) substrate. In the semiconductor substrate 12, the photoelectric conversion unit 20 is formed in each of the regions of the respective pixels 8. That is, the plurality of photoelectric conversion units 20 is arranged in a two-dimensional array in the semiconductor substrate 12. The photoelectric conversion units 20 each form a photodiode by a p-n junction, and generates charge corresponding to the amount of received light. Furthermore, the photoelectric conversion unit 20 accumulates charge generated by the photoelectric conversion in electrostatic capacitance (junction capacitance) generated in the p-n junction.

Furthermore, in the semiconductor substrate 12, a trench portion 21 is formed in all the regions between the adjacent photoelectric conversion units 20. That is, the trench portion 21 is formed in a lattice shape in the semiconductor substrate 12. FIG. 2 illustrates a case where the trench portion 21 is configured to have an opening on the light incident surface (hereinafter, also referred to as “back surface S3”) side of the semiconductor substrate 12.

The insulating film 13 is disposed on the back surface S3 side of the semiconductor substrate 12 and continuously covers the entire back surface S3. Furthermore, the insulating film 13 is embedded in the trench portion 21. As a material of the insulating film 13, for example, silicon oxide (SiO₂) and silicon nitride (SiN) can be used.

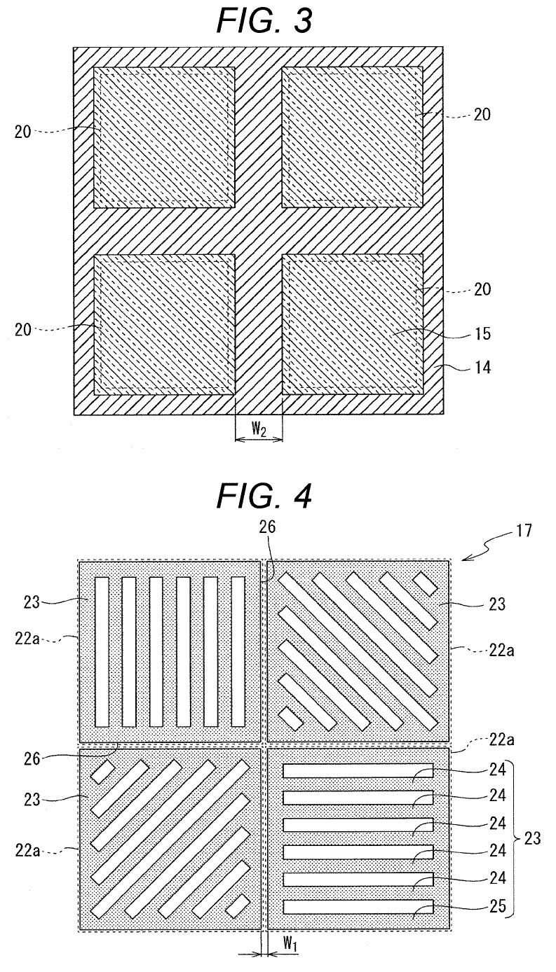

The light-shielding film 14 is disposed on the light incident surface (hereinafter, also referred to as “back surface S4”) side of the insulating film 13, and is formed to open the light incident surface of each of the photoelectric conversion units 20 as illustrated in FIG. 3. That is, the light-shielding film 14 is disposed between the semiconductor substrate 12 and a metal structure 23. Furthermore, the light-shielding film 14 is formed at a position overlapping the trench portion 21 formed in a lattice shape. In other words, it can be said that the light-shielding film 14 is formed along the gap between the photoelectric conversion units 20 to cover the light incident surface side of the gap between the photoelectric conversion units 20. As a result, for example, in two of the pixels 8 adjacent to each other, in a case where light is obliquely incident on the microlens 27 of one pixel 8 and the incident light travels to the photoelectric conversion unit 20 of the other adjacent pixel 8, the light-shielding film 14 can block the traveling light. As a material of the light-shielding film 14, for example, aluminum (Al), tungsten (W), or copper (Cu) can be used. FIG. 3 is a view illustrating a cross-sectional configuration of the light-shielding film 14 taken along line B-B in FIG. 2.

The planarizing film 15 is disposed on the back surface S4 side of the insulating film 13, and continuously covers the back surface S4 and the light-shielding film 14 to make the back surface S1 side of the light-receiving layer 16 a flat surface. As a material of the insulating film 13, for example, silicon oxide (SiO₂) and silicon nitride (SiN) can be used.

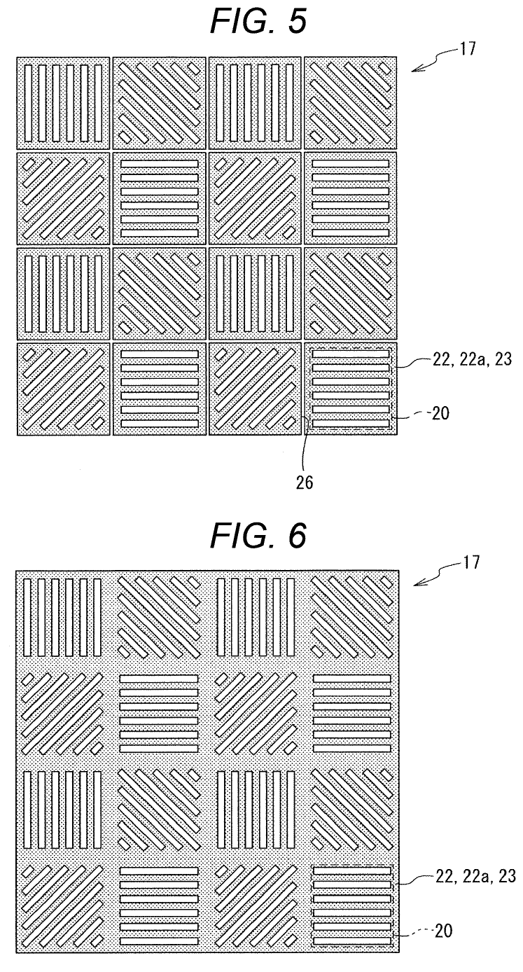

The optical filter array 17 is disposed on the light incident surface side (back surface S1) of the planarizing film 15 and includes a plurality of optical filters 22 arranged in a two-dimensional array so as to correspond to the respective pixels 8. That is, the plurality of optical filters 22 is formed for the respective photoelectric conversion units 20. FIGS. 2, 4, and 5 illustrate a case where a wire grid polarizer 22a is used as the optical filter 22. FIG. 4 is a view illustrating a cross-sectional configuration of the wire grid polarizers 22a taken along line C-C in FIG. 2. Furthermore, FIG. 5 is a view illustrating a cross-sectional configuration of the wire grid polarizers 22a in a range wider than that in FIG. 4. The wire grid polarizers 22a have a metal structure 23 including a metal material. The metal structure 23 integrally includes a plurality of strip-shaped conductors 24 arranged in parallel at a predetermined pitch, and a frame-shaped outer peripheral portion 25 arranged to surround a region where the plurality of strip-shaped conductors 24 is located and connected to an end portion of each of the strip-shaped conductors 24. As the strip-shaped conductor 24, for example, a conductor (wire) formed in a linear shape or a rectangular parallelepiped shape can be used. Furthermore, examples of the metal material include aluminum (Al), copper (Cu), tungsten (W), titanium (Ti), tantalum (Ta), silicon (Si), platinum (Pt), gold (Au), and cobalt (Co). In particular, white aluminum (Al) is preferable because its light absorptivity is low and reflectance is high. Furthermore, an antireflection layer (not illustrated) may be formed on the light incident surface side of each strip-shaped conductor 24.

Note that the longitudinal direction of the strip-shaped conductors 24 of the wire grid polarizers 22a may be different between the wire grid polarizers 22a. For example, FIGS. 4 and 5 illustrate the case of using four types of wire grid polarizers 22a in which the longitudinal directions of the strip-shaped conductors 24 are different by 45°. Furthermore, FIG. 5 illustrates an example in which the optical filters 22 are arranged such that the optical filters 22 having different transmission characteristics are adjacent to each other in the optical filter array 17.

Here, free electrons in the strip-shaped conductors 24 vibrate following an electric field of light incident on the strip-shaped conductors 24, and radiate the reflected wave. Therefore, incident light that vibrates the electric field in a direction perpendicular to the direction in which the plurality of strip-shaped conductors 24 is arranged, that is, in a direction parallel to the longitudinal direction of the strip-shaped conductors 24 allows free electrons in the strip-shaped moving bodies 24 to freely vibrate, and thus the free electrons radiate more reflected light. Therefore, the incident light that vibrates the electric field in a direction parallel to the longitudinal direction of the strip-shaped conductors 24 is not transmitted through the wire grid polarizer 22a but reflected. On the other hand, the light that vibrates the electric field in the direction perpendicular to the longitudinal direction of the strip-shaped conductors 24 limits the vibration of free electrons in the strip-shaped moving bodies 24, and thus the radiation of the reflected light from the strip-shaped conductors 24 is reduced. Therefore, the attenuation of the incident light that vibrates the electric field in a direction perpendicular to the longitudinal direction of the strip-shaped conductors 24 caused by the wire grid polarizer 22a is reduced, and can be transmitted through the wire grid polarizer 22a.

Furthermore, in the optical filter array 17, a slit portion 26 is formed between some of the metal structures 23 or between all of the metal structures 23. FIG. 4 illustrates a case where the slit portion 26 is formed between all the metal structures 23. That is, the slit portion 26 is formed in a lattice shape in the optical filter array 17. The slit portion 26 penetrates a region where the metal structure 23 is located (a region of the optical filter array 17 in FIG. 4) in the thickness direction of the metal structure 23. As a result, the slit portion 26 sections the metal structures 23 to make a plurality of regions where the plurality of metal structures 23 is located. FIG. 4 illustrates a case where a region where the plurality of metal structures 23 is located is sectioned into regions corresponding to the pixels 8.

Furthermore, the shape of the portion of the slit portion 26 extending along the gap between the photoelectric conversion units 20 when viewed from the direction orthogonal to the back surface S3 of the semiconductor substrate 12 (in plan view) is linear. The linear shape can reduce the area of the slit portion 26 in plan view, can increase the area of the metal structure 23, and can increase the amount of incident light transmitted through the optical filter 22.

In addition, the slit width W₁ of the slit portion 26 is made smaller than the width W₂ of the portion of the light-shielding film 14 extending along the gap between the photoelectric conversion units 20. By setting the width relationship W₁<W₂, the light passing through the slit portion 26 can be blocked by the light-shielding film 14, and color mixing between the pixels 8 can be suppressed.

The microlens array 18 is disposed on the light incident surface (hereinafter, also referred to as “back surface S5”) side of the optical filter array 17 and includes a plurality of microlenses 27 arranged in a two-dimensional array so as to correspond to the respective pixels 8. That is, one of the microlenses 27 is formed for one photoelectric conversion unit 20. Each of the microlenses 27 condenses image light from a subject and guides the condensed image light into the photoelectric conversion unit 20 via the optical filter 22.

The wiring layer 19 is disposed on the front surface S2 side of the semiconductor substrate 12. The wiring layer 19 includes an interlayer insulating film and wirings (not illustrated) stacked in a plurality of layers with the interlayer insulating film interposed therebetween. Then, the wiring layer 19 drives a pixel transistor of each pixel 8 through the plurality of layers of wiring.

In the solid-state imaging device 1 having the above configuration, light is emitted from the back surface S3 side of the semiconductor substrate 12, the emitted light passes through the microlens 27 and the optical filter 22, and the transmitted light is photoelectrically converted by the photoelectric conversion unit 20 to generate signal charge. Then, the generated signal charge is output as a pixel signal from the vertical signal line 10 in FIG. 1 formed by the wiring in the wiring layer 19.

Generally, a metal material has a property that metal atoms move so that stress is relaxed. In a process of manufacturing the solid-state imaging device 1, films having various intrinsic stresses are used, or thermal stress is generated by applying heat of several hundred degrees and then returning the temperature to room temperature, so that stress is applied to the metal structure 23 including a metal material. Therefore, in the metal structure 23, metal atoms are moved so as to relax the stress. In addition, minute voids are present in the metal material. Therefore, in the metal structure 23, voids also move along with movement of metal atoms. Here, for example, as illustrated in FIG. 6, a case is considered in which, in the optical filter array 17, no slit portion 26 is formed between the metal structures 23, and the adjacent metal structures 23 are integrated with each other by the outer peripheral portions 25. In the case of the structure illustrated in FIG. 6, the metal atoms can freely move in all the metal structures 23, and thus voids in the metal material are likely to grow, and there is a possibility that large voids are formed in the metal structures 23. That is, in the structure illustrated in FIG. 6, there is a possibility that metal atoms move to relax the stress, and a phenomenon in which voids grow in the metal structure 23 (stress migration) may occur. Then, as large voids are formed in the metal structures 23, the sensitivity value of the pixel 8 having the metal structure 23 in which large voids are formed increases, and a defective pixel may be generated.

On the other hand, in the solid-state imaging device 1 according to the first embodiment, the slit portion 26 that spatially sections the metal structures 23 is formed between the adjacent metal structures 23. Therefore, the adjacent metal structures 23 are separated, so that the movement of the metal atoms of the metal structure 23 can be inhibited to retain the metal atoms in some of the metal structures 23, and the growth of voids in the metal structure 23 can be suppressed. Therefore, the occurrence of defects in the optical filter 22 due to stress migration can be suppressed, and the generation of defective pixels (for example, a point defect) can be suppressed.

Furthermore, in the solid-state imaging device 1 according to the first embodiment, the optical filter 22 is formed for each photoelectric conversion unit 20, and the slit portion 26 is formed between all the metal structures 23. As a result, the movement range of the metal atoms can be limited within one metal structure 23, and in the metal structure 23, the growth of voids can be appropriately suppressed, so that the formation of large voids can be suppressed.

### [1-3 Modifications]

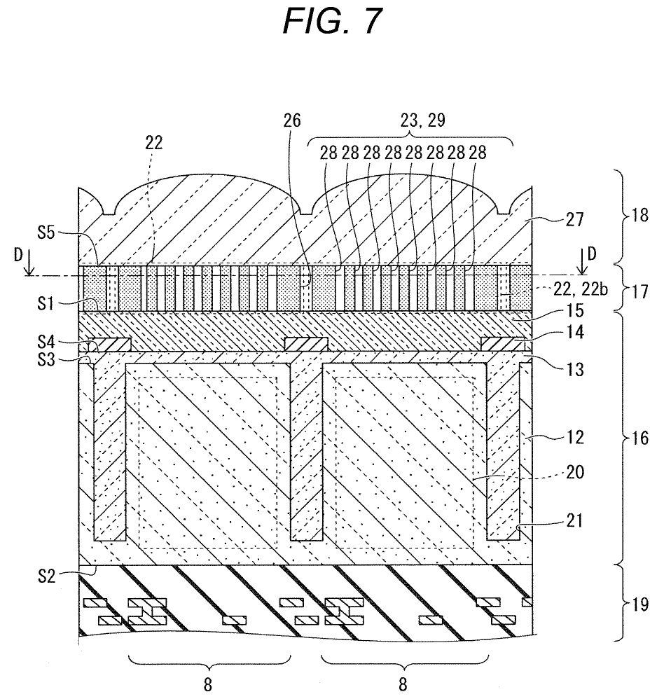

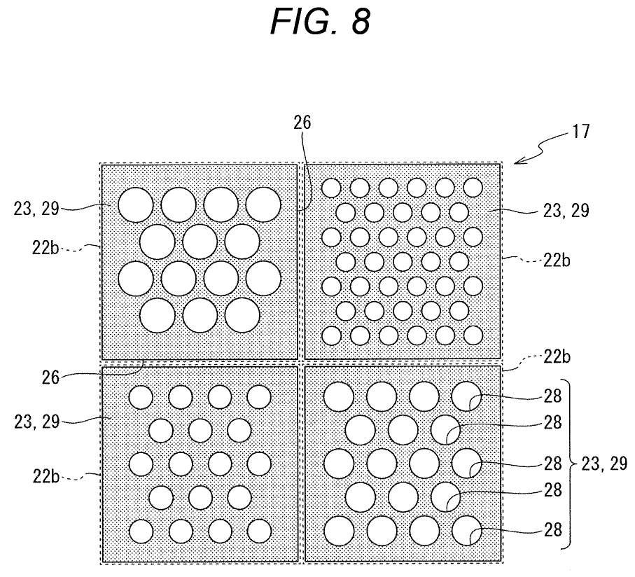

(1) Note that, in the first embodiment, an example in which the wire grid polarizer 22a is used as the optical filter 22 has been described, but other configurations can also be employed. For example, as illustrated in FIGS. 7 and 8, a plasmon filter 22b may be used. FIG. 7 is a view illustrating a cross-sectional configuration of the solid-state imaging device 1 according to a modification. Furthermore, FIG. 8 is a view illustrating a cross-sectional configuration of the wire grid polarizers 22a taken along line D-D in FIG. 7. The plasmon filters 22b are filters utilizing surface plasmon resonance. The plasmon filters 22b each include, as the metal structure 23, a metal film 29 having a plurality of holes 28 arranged in a two-dimensional array. In the plasmon filter 22b, surface plasmon having a specific frequency component determined according to a period of the holes 28 (pitch between the holes 28) is excited and propagated at an interface between the metal film 29 and an oxide film or the like (not illustrated) covering the metal film 29, and thus the plasmon filter 22b transmits light in a predetermined band. Examples of the metal material of the metal film 29 include aluminum (Al), copper (Cu), tungsten (W), titanium (Ti), tantalum (Ta), silicon (Si), platinum (Pt), gold (Au), and cobalt (Co), similarly to the wire grid polarizer 22a. In particular, aluminum (Al) is preferred.

Note that, here, the spectroscopy by the propagating surface plasmon of the plasmon filter 22b has been described as an example. However, the spectroscopy is possible by a similar principle with a localized surface plasmon resonance filter (localized surface plasmon resonance filter) having a structure in which nanoscale metallic columnar structures (metal nanostructures) are periodically arranged.

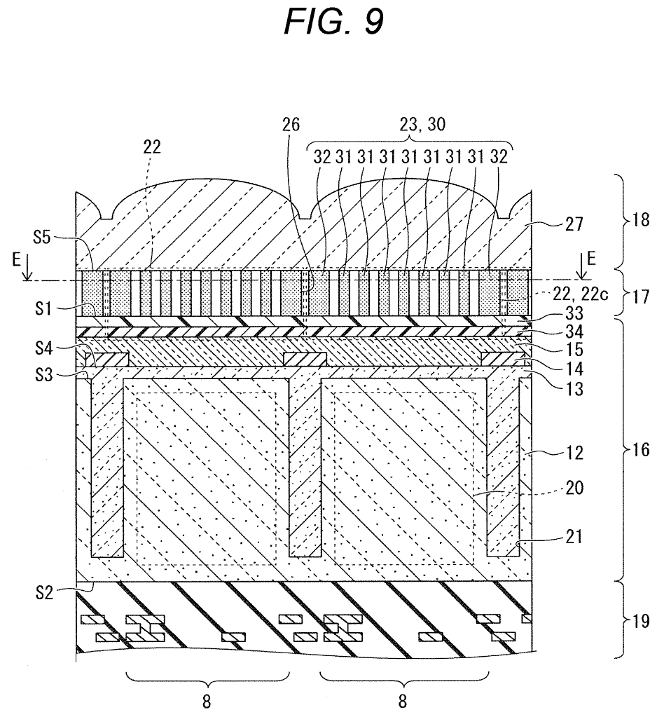

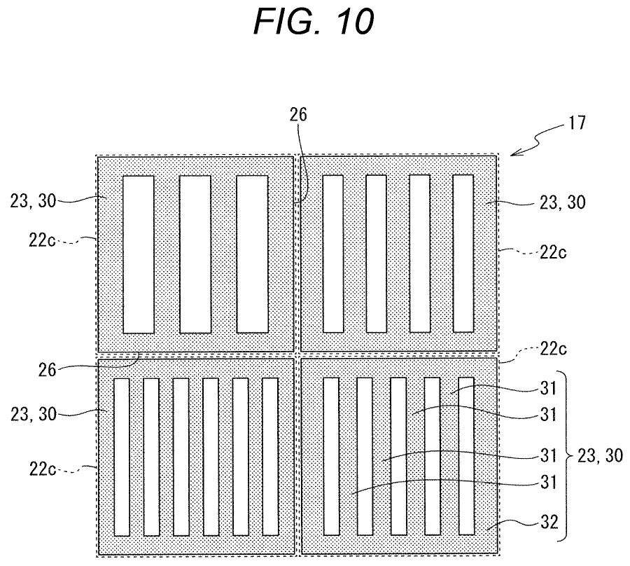

(2) Furthermore, for example, as illustrated in FIGS. 9 and 10, a guided mode resonance (GMR) filter 22c may be used as the optical filter 22. FIG. 9 is a view illustrating a cross-sectional configuration of the solid-state imaging device 1 according to a modification. Furthermore, FIG. 10 is a view illustrating a cross-sectional configuration of the GMR filter 22c taken along line E-E in FIG. 9. The GMR filter 22c is a filter utilizing guided mode resonance. The GMR filter 22c includes a diffraction grating 30 as the metal structure 23. The diffraction grating 30 integrally includes a plurality of strip-shaped conductors 31 arranged in parallel at a predetermined pitch, and a frame-shaped outer peripheral portion 32 arranged to surround a region where the plurality of strip-shaped conductors 31 is located and connected to an end portion of each of the strip-shaped conductors 31. Furthermore, the GMR filter 22c includes a waveguide including a cladding layer 33 and a core layer 34 in addition to the diffraction grating 30. The diffraction grating 30, the cladding layer 33, and the core layer 34 are stacked in this order from the light incident side. The GMR filter 22c transmits only light having a wavelength that matches the diffraction angle of the diffraction grating 30 and the waveguide mode of the waveguide (cladding layer 33 and core layer 34), so that light in a predetermined band is transmitted. Examples of the metal material of the diffraction grating 30 include aluminum (Al), copper (Cu), tungsten (W), titanium (Ti), tantalum (Ta), silicon (Si), platinum (Pt), gold (Au), and cobalt (Co), similarly to the wire grid polarizer 22a. In particular, aluminum (Al) is preferred. Furthermore, as a material of the cladding layer 33, for example, silicon oxide (SiO₂) can be used. Furthermore, as a material of the core layer 34, for example, silicon nitride (SiN), tantalum dioxide (TaO₂), or titanium oxide (TiO₂) can be used.

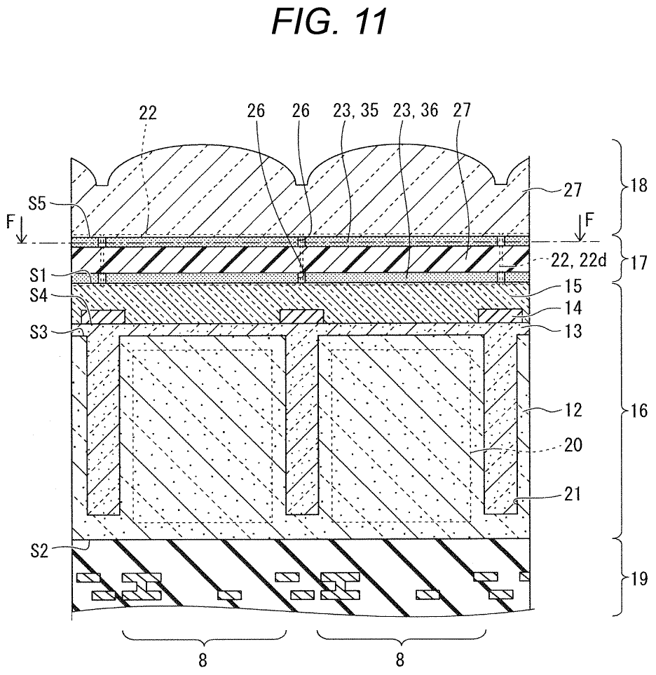

(3) Furthermore, for example, as illustrated in FIGS. 11 and 12, a Fabry-Perot (FP) filter 22d may be used as the optical filter 22. FIG. 11 is a view illustrating a cross-sectional configuration of the solid-state imaging device 1 according to a modification. Furthermore, FIG. 12 is a view illustrating a cross-sectional configuration of the FP filter 22d taken along line F-F in FIG. 11. The FP filter 22d is a filter utilizing Fabry-Perot interference. The FP filter 22d includes an upper mirror layer 35 and a lower mirror layer 36 as the metal structure 23. Furthermore, the FP filter 22d includes a resonator layer 37 in addition to the upper mirror layer 35 and the lower mirror layer 36. The upper mirror layer 35, the resonator layer 37, and the lower mirror layer 36 are stacked in this order from the light incident side. Furthermore, one resonator layer 37 is formed for all the FP filters 22d and is shared. In the FP filter 22d, light is multiply reflected by the reflection surface of the upper mirror layer 35 and the reflection surface of the lower mirror layer 36 and the multiply reflected light is interfered by the resonator layer 37, so that the FP filter 22d transmits light in a predetermined band. The FP filter 22d having different transmission wavelengths and reflection wavelengths can be configured by varying the layer thickness (optical length) of the resonator layer 37. Examples of the material of the upper mirror layer 35 and the lower mirror layer 36 include aluminum (Al), copper (Cu), tungsten (W), titanium (Ti), tantalum (Ta), silicon (Si), platinum (Pt), gold (Au), and cobalt (Co), similarly to the wire grid polarizer 22a. In particular, silver (Ag) is preferable. Furthermore, as a material of the resonator layer 37, for example, a resin or a dielectric can be used.

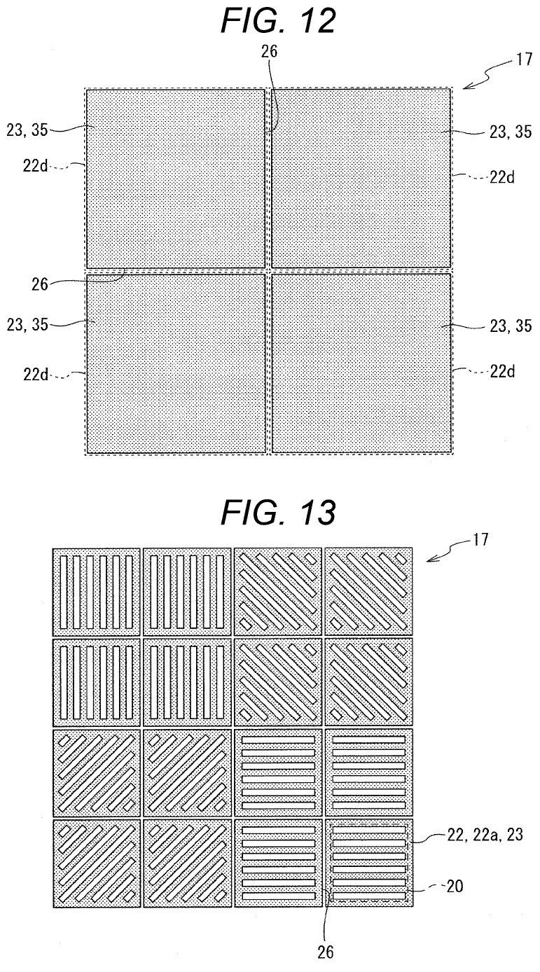

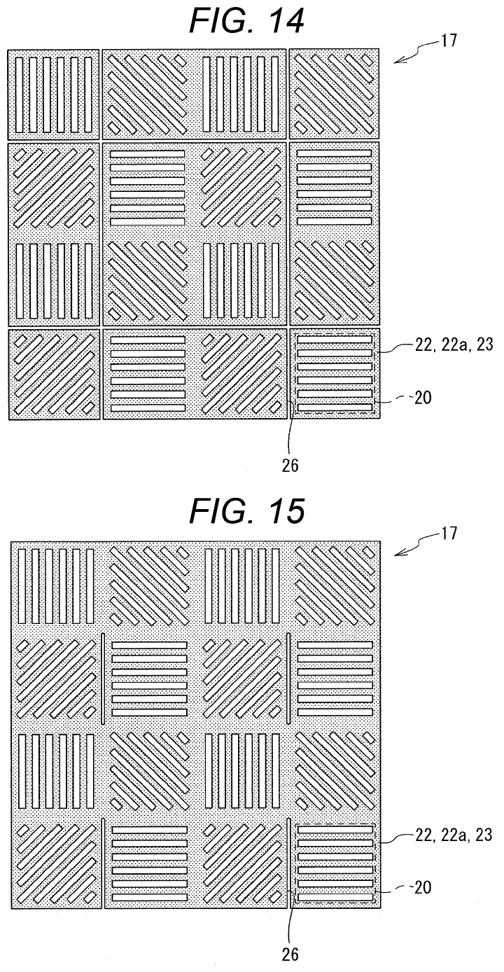

(4) Furthermore, in the first embodiment, an example has been described in which the optical filters 22 are arranged such that the adjacent optical filters 22 have different transmission characteristics in the optical filter array 17, but other configurations can also be employed. For example, as illustrated in FIG. 13, there may be a portion where the optical filters 22 having the same transmission characteristics are adjacent to each other. FIG. 13 illustrates a case where the four optical filters 22 arranged in a 2×2 array have the same transmission characteristics.

(5) Furthermore, in the first embodiment, an example in which the optical filter 22 is formed for each photoelectric conversion unit 20 and the slit portion 26 is formed between all the metal structures 23 has been described, but other configurations can be employed. For example, as illustrated in FIGS. 14 and 15, a configuration in which the optical filter 22 is formed for each photoelectric conversion unit 20, and the slit portion 26 is formed between only some of the metal structures 23 may be adopted. FIG. 14 illustrates a case where sets of the metal structures 23 arranged in a 2×2 array are connected to each other, the slit portion 26 is formed only between sets of the metal structures 23 arranged in a 2×2 array to surround the sets of the metal structures 23 arranged in a 2×2 array. Furthermore, FIG. 15 illustrates a case where the slit portion 26 is discontinuously formed and the slit portion 26 does not surround the metal structure(s) 23.

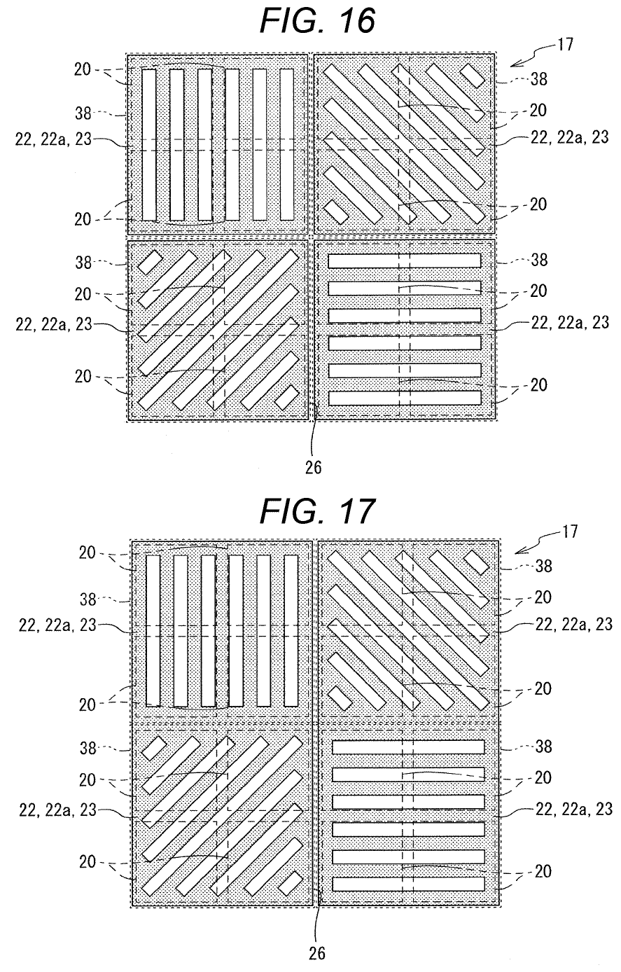

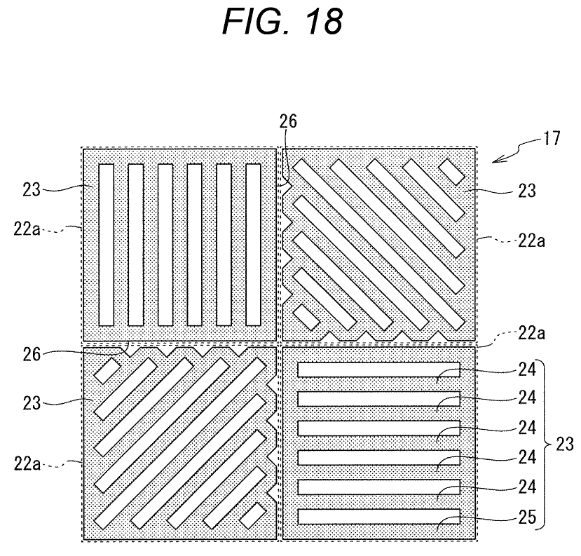

(6) Furthermore, for example, as illustrated in FIGS. 16 and 17, a configuration in which the optical filter 22 is formed for each photoelectric conversion unit group 38 including two or more of the photoelectric conversion units 20, and the slit portion 26 is formed between some of the metal structures 23 or between all of the metal structures 23 may be adopted. FIG. 16 illustrates a case where the optical filter 22 is formed for each photoelectric conversion unit group 38 including the photoelectric conversion units 20 arranged in a 2×2 array, and the slit portion 26 is formed between all the metal structures 23. Furthermore, FIG. 17 illustrates a case where the optical filter 22 is formed for each photoelectric conversion unit group 38, and the slit portion 26 is formed between only some of the metal structures 23.

(7) Furthermore, in the first embodiment, an example has been described in which the slit width W₁ of the slit portion 26 is smaller than the width W₂ of the portion of the light-shielding film 14 extending along the gap between the photoelectric conversion units 20, but other configurations can be employed. For example, the slit width W₁ of the slit portion 26 may be smaller than the wavelength of light incident on the slit portion 26. As an example, in a case where there is a color filter on the optical path to the slit portion 26, the slit width W₁ may be smaller than the lower limit of the cutoff wavelength of the color filter. As another example, in a case where the use environment is limited and only light of a specific wavelength range reaches the slit portion 2, the slit width W₁ may be smaller than the shortest wavelength in the specific wavelength range.

(8) Furthermore, in the first embodiment, an example has been described in which the shape of the portion of the slit portion 26 extending along the gap between the photoelectric conversion units 20 when viewed from the direction orthogonal to the light incident surface of the semiconductor substrate 12 (in plan view), but other configurations can be employed. For example, as illustrated in FIG. 18, the shape of the portion of the slit portion 26 extending along the gap between the photoelectric conversion units 20 in a plan view may be a shape including a portion having a slit width W₁ different from the surrounding part. FIG. 18 illustrates a case where the shape of the inner wall surface of a part of the slit portion 26 in plan view is a polygonal line shape, that is, a zigzag line shape obtained by connecting a plurality of line segments.

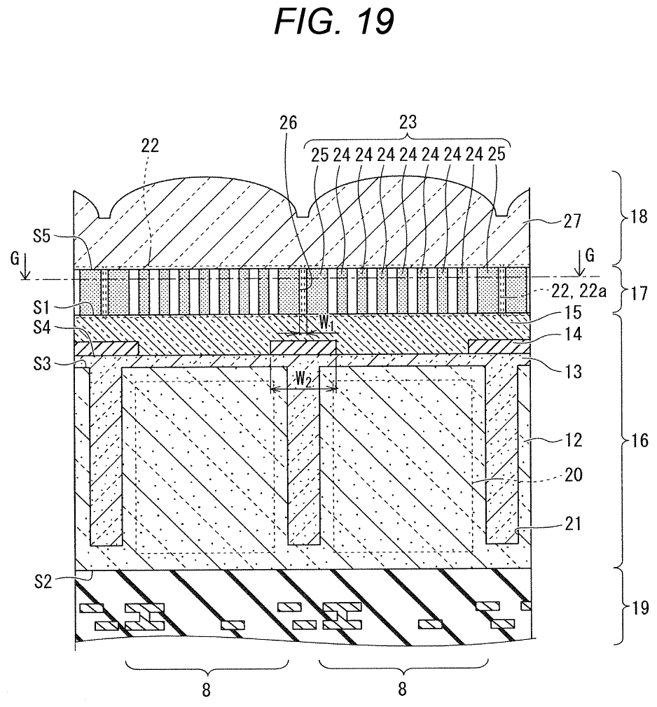

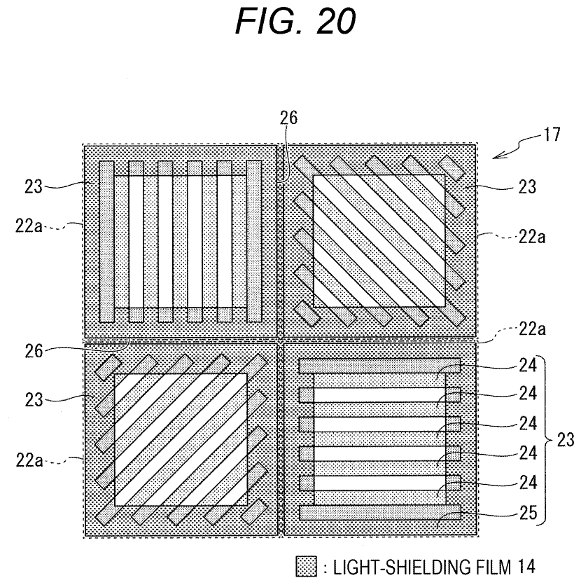

(9) Furthermore, in the first embodiment, an example has been described in which the light-shielding film 14 is formed at a position overlapping the region where the outer peripheral portion 25 of the metal structure 23 is located and not overlapping the region where the strip-shaped conductors 24 are located, but other configurations can be employed. For example, as illustrated in FIGS. 19 and 20, a configuration may be adopted in which when viewed from a direction orthogonal to the back surface S3 of the semiconductor substrate 12 (in plan view), the light-shielding film 14 is formed so as to extend further than a region where the outer peripheral portion 25 of the metal structure 23 is located to a region where the strip-shaped conductor 24 is located. As a result, the light having passed through the slit portion 26 can be more reliably blocked by the light-shielding film 14, and color mixing between the pixels 8 can be more reliably suppressed.

### 2. SECOND EMBODIMENT

### [2-1 Configuration of Main Part]

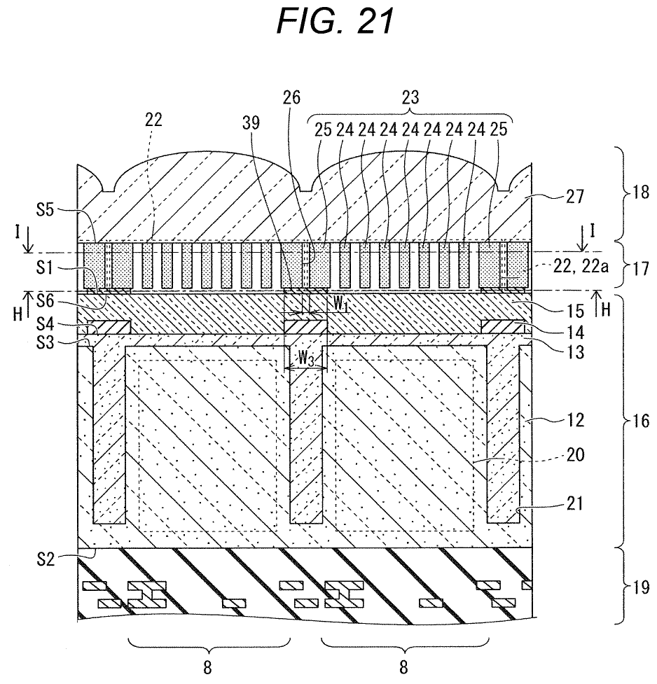

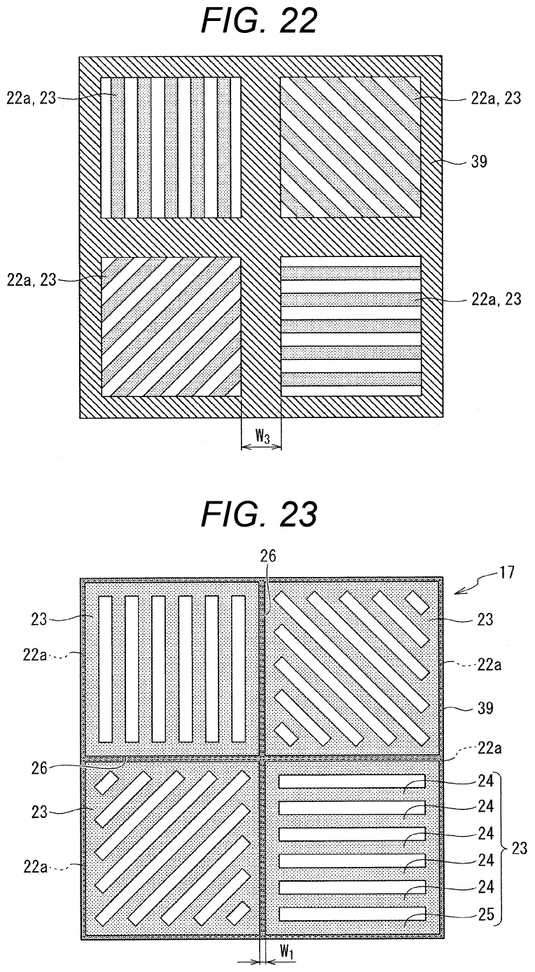

Next, a solid-state imaging device 1 according to a second embodiment of the present disclosure will be described. An overall configuration of the solid-state imaging device 1 according to the second embodiment is similar to that in FIG. 1, and thus illustration thereof will be omitted. FIG. 21 is a view illustrating a cross-sectional configuration of the solid-state imaging device 1 according to the second embodiment. FIG. 22 is a view illustrating a cross-sectional configuration of the solid-state imaging device 1 taken along line H-H in FIG. 21. FIG. 23 is a view illustrating a cross-sectional configuration of the solid-state imaging device 1 taken along line I-I in FIG. 21. In FIGS. 21 and 23, portions corresponding to FIGS. 2 and 3 are denoted by the same reference numerals, and redundant description will be omitted.

As illustrated in FIGS. 21 to 23, the second embodiment is different from the first embodiment in that a conductive portion 39 electrically connecting metal structures 23 sectioned by a slit portion 26 is provided. FIGS. 21 to 23 illustrate a case where the conductive portion 39 is disposed on a surface (surface S6) side of the metal structure 23 on the semiconductor substrate 12 side and is electrically connected to a surface S6 of the metal structure 23. Specifically, the conductive portion 39 is disposed on the surface S6 side of an optical filter array 17, and is formed along the slit portion 26 so as to cover the opening of the slit portion 26 on the surface S6 side as illustrated in FIG. 22. That is, the conductor portion 39 is formed in a lattice shape. Furthermore, a width W₃ of a portion of the conductive portion 39 extending along the slit portion 26 is larger than a slit width W₁ of the slit portion 26. Thus, the conductive portion 39 is disposed across the metal structures 23, and electrically connects the metal structures 23 sectioned by the slit portion 26. As a material of the conductive portion 39, for example, a conductive material different from the metal material included in the metal structure 23 can be used. Examples of the material include conductive materials resistant to stress migration, such as titanium (Ti), titanium nitride (TiN), and tantalum (Ta). In particular, by using titanium (Ti), titanium nitride (TiN), or tantalum (Ta), movement of metal atoms can be inhibited in a portion of the metal structure 23 in contact with the conductive portion 39, and stress migration can be suppressed.

Here, in a case where, for example, the metal structures 23 are sectioned by the slit portion 26, the metal material is in a floating state during processing of the metal material, so that arcing may occur.

On the other hand, according to the solid-state imaging device 1 according to the second embodiment, the metal structures 23 are electrically connected by the conductive portion 39, and thus it is possible to prevent the metal material of the metal structure 23 from being in a floating state during processing of the metal material of the metal structure 23, and then to suppress the occurrence of arcing. Note that, at this time, since the conductive material of the conductive portion 39 is a material different from the metal material of the metal structure 23, the metal atoms of the metal structure 23 do not move into the conductive material of the conductive portion 39.

Furthermore, according to the solid-state imaging device 1 according to the second embodiment, the conductor portion 39 is disposed on the surface (surface S6) of the metal structure 23 on the semiconductor substrate 12 side to cover the opening of the slit portion 26. Therefore, the light having passed through the slit portion 26 can be blocked by the conductive portion 39, the light having passed therethrough can be prevented from entering a photoelectric conversion unit 20, and then color mixing between the pixels 8 can be suppressed.

### [2-2 Modifications]

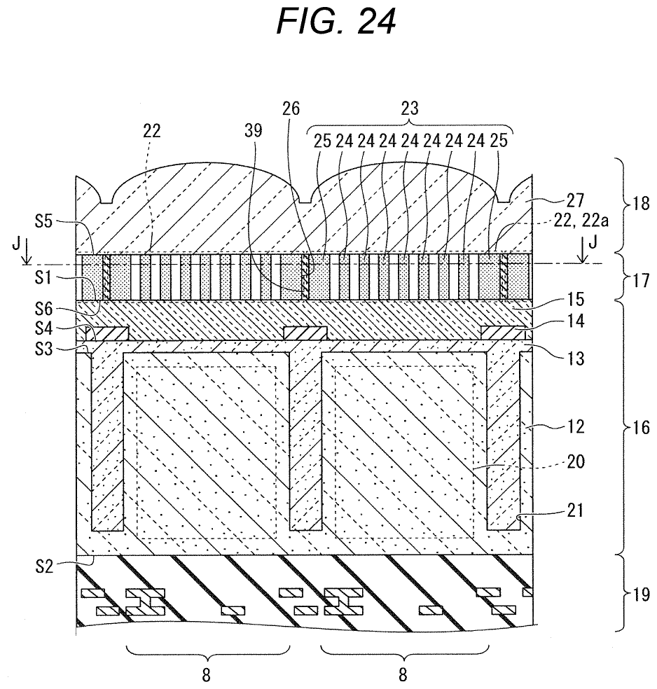

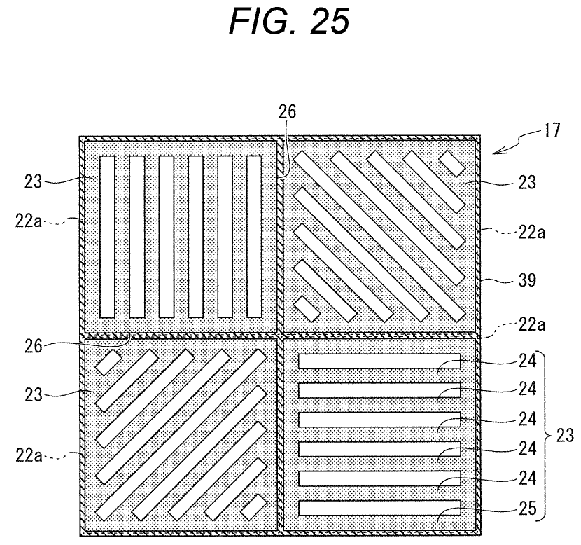

(1) Note that, in the second embodiment, an example has been described in which the conductive portion 39 is disposed between the metal structure 23 and the semiconductor substrate 12 to electrically connect the semiconductor substrate 12 to the surface S6 of the metal structure 23, but other configurations may be employed. For example, as illustrated in FIGS. 24 and 25, the conductive portion 39 may be disposed in the slit portion 26 and electrically connected to the surface of the metal structure 23 on the slit portion 26 side. FIGS. 24 and 25 illustrate a case where the conductive portion 39 is formed by embedding a conductive material in the slit portion 26, that is, a case where the conductive portion 39 is formed by filling the slit portion 26 with a conductive material. The conductive portion 39 is formed in a lattice shape similar to the slit portion 26. Thus, the conductive portion 39 electrically connects the metal structures 23 sectioned by the slit portion 26. Furthermore, by using, as a metal material of the conductor portion 39, titanium (Ti), titanium nitride (TiN), or tantalum (Ta), movement of metal atoms in a portion of the metal structure 23 in contact with the conductive portion 39, that is, in the inner wall surface of the slit portion 26 can be inhibited and stress migration can be suppressed. Furthermore, the light incident on the slit portion 26 can be blocked by the conductive portion 39, the incident light can be prevented from traveling into the photoelectric conversion unit 20, and then color mixing between the pixels 8 can be suppressed. That is, the conductive portion 39 can function as a light shielding portion that blocks transmission of light in the slit portion 26.

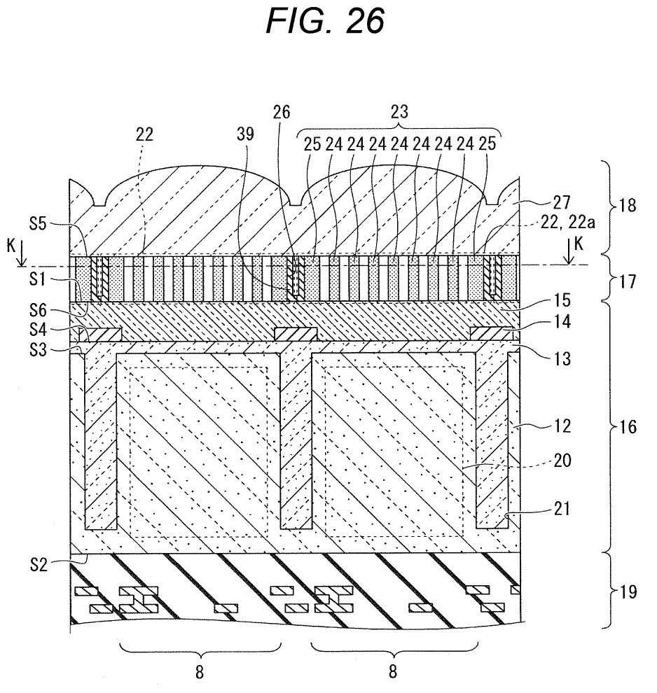

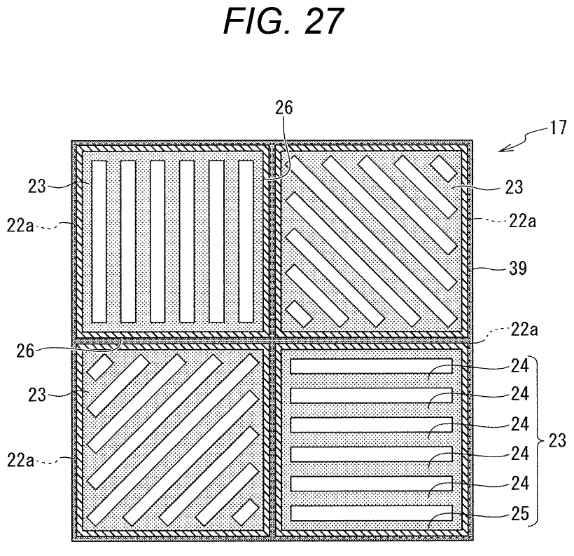

Furthermore, in a case where the configuration in which the conductive portion 39 is employed in the slit portion 26 is employed, as illustrated in FIGS. 26 and 27, the shape of the conductive portion 39 may be in a U-shaped groove shape that covers each of the inner wall surfaces of the slit portion 26 and closes the opening of the slit portion 26 on the semiconductor substrate 12 side.

(2) Furthermore, in the solid-state imaging device 1 according to the second embodiment, various configurations described in Modifications (1) to (9) of the first embodiment can also be employed.

(3) Furthermore, the present technology can be applied to all photodetection devices including a ranging sensor that measures a distance and may be referred to as a time of flight (ToF) sensor, or the like, in addition to the solid-state imaging device 1 as the image sensor described above. A ranging sensor is a sensor that emits irradiation light toward an object, detects reflected light that is the irradiation light reflected by a surface of the object, and calculates the distance to the object on the basis of a flight time from the emission of the irradiation light till the reception of the reflected light. As a light receiving pixel structure of the ranging sensor, the structure of the pixel 8 described above may be employed.

### 3. THIRD EMBODIMENT

The technology according to the present disclosure (present technology) may be applied to various electronic devices.

FIG. 28 is a diagram illustrating an example of a schematic configuration of an imaging device (video camera, digital still camera, or the like) as an electronic device to which the present technology is applied.

As illustrated in FIG. 28, an imaging device 1000 is provided with a lens group 1001, a solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to each other via a bus line 1007.

The lens group 1001 guides incident light (image light) from a subject to the solid-state imaging device 1002 to form an image on a light incident surface (pixel region) of the solid-state imaging device 1002.

The solid-state imaging device 1002 includes the above-described CMOS image sensor according to the first embodiment. The solid-state imaging device 1002 converts an amount of incident light an image of which is formed on the light incident surface by the lens group 1001 into an electric signal in units of pixels and supplies the electric signal to the DSP circuit 1003 as a pixel signal.

The DSP circuit 1003 performs predetermined image processing on the pixel signal supplied from the solid-state imaging device 1002. Then, the DSP circuit 1003 supplies an image signal subjected to the image processing to the frame memory 1004 frame by frame to make the frame memory 1004 temporarily store the image signal.

The monitor 1005 includes, for example, a panel type display device such as a liquid crystal panel or an organic electro luminescence (EL) panel. The monitor 1005 displays an image (moving image) of the subject on the basis of the pixel signal for each frame temporarily stored in the frame memory 1004.

The memory 1006 includes a DVD, a flash memory, and the like. The memory 1006 reads and records the pixel signal for each frame temporarily stored in the frame memory 1004.

Note that the electronic device to which the solid-state imaging device 1 can be applied is not limited to the imaging device 1000, and the solid-state imaging device 1 can also be applied to other electronic devices. Furthermore, the solid-state imaging device 1 according to the first embodiment is used as the solid-state imaging device 1002, but other configurations can also be employed. For example, a configuration may be employed in which another photodetection device to which the present technology is applied is used, such as the solid-state imaging device 1 according to the second embodiment or the solid-state imaging device 1 according to the modifications of the first to second embodiments.

Note that the present disclosure may also have the following configurations.

(1)

A photodetection device including:
a semiconductor substrate on which a plurality of photoelectric conversion units is formed; and
a plurality of optical filters disposed on a light incident surface side of the semiconductor substrate, in which
each of the optical filters includes a metal structure including a metal material of the same kind, and
the photodetection device further includes, between the metal structures, a slit portion spatially sectioning the metal structures.

(2)

The photodetection device according to (1), in which
the optical filters are formed for the respective photoelectric conversion units, and
the slit portion is formed between some of the metal structures or between all of the metal structures.

(3)

The photodetection device according to (1), in which
the optical filter is formed for each of photoelectric conversion unit groups each including two or more of the photoelectric conversion units, and
the slit portion is formed between some of the metal structures or between all of the metal structures.

(4)

The photodetection device according to any one of (1) to (3), further including
a conductive portion that electrically connects the metal structures sectioned by the slit portion, in which
the conductive portion includes a conductive material different from a metal material included in the metal structure.

(5)

The photodetection device according to (4), in which
the conductive portion is disposed on a surface side of the metal structure on a side of the semiconductor substrate and is electrically connected to a surface of the metal structure on the semiconductor substrate side.

(6)

The photodetection device according to (4), in which
the conductive portion is disposed in the slit portion and is electrically connected to a surface of the metal structure on the slit portion side.

(7)

The photodetection device according to any one of (1) to (4), in which
a light shielding portion that is disposed in the slit portion and blocks transmission of light in the slit portion.

(8)

The photodetection device according to any one of (1) to (7), including
a light-shielding film disposed between the semiconductor substrate and the metal structures and formed along a gap between the photoelectric conversion units to cover a light incident surface side of the gap between the photoelectric conversion units, in which
a slit width of the slit portion is smaller than a width of a portion of the light-shielding film extending along the gap between the photoelectric conversion units.

(9)

The photodetection device according to any one of (1) to (7), in which
a slit width of the slit portion is smaller than a wavelength of light incident on the slit portion.

(10)

The photodetection device according to any one of (1) to (9), in which
a shape of a portion of the slit portion extending along a gap between the photoelectric conversion units when viewed from a direction orthogonal to the light incident surface of the semiconductor substrate is linear.

(11)

The photodetection device according to any one of (1) to (9), in which
a shape of a portion of the slit portion extending along a gap between the photoelectric conversion units when viewed from a direction orthogonal to the light incident surface of the semiconductor substrate is a shape including a portion having a slit width different from a surrounding part.

(12)

The photodetection device according to any one of (1) to (11), in which
the optical filter is a wire grid polarizer.

(13)

The photodetection device according to any one of (1) to (11), in which
the optical filter is a plasmon filter.

(14)

The photodetection device according to any one of (1) to (11), in which
the optical filter is a guided mode resonance (GMR) filter.

(15)

The photodetection device according to any one of (1) to (11), in which
the optical filter is a Fabry-Perot (FP) filter.

(16)

An electronic device including
a photodetection device including: a semiconductor substrate on which a plurality of photoelectric conversion units is formed; and a plurality of optical filters disposed on a light incident surface side of the semiconductor substrate, in which each of the optical filters includes a metal structure including a metal material of the same kind, and the photodetection device further includes, between the metal structures, a slit portion spatially sectioning the metal structures.

### REFERENCE SIGNS LIST

1 Solid-state imaging device
2 Pixel region
3 Vertical drive circuit
4 Column signal processing circuit
5 Horizontal drive circuit
6 Output circuit
7 Control circuit
8 Pixel
9 Pixel drive wiring
10 Vertical signal line
11 Horizontal signal line
12 Semiconductor substrate
13 Insulating film
14 Light-shielding film
15 Planarizing film
16 Light-receiving layer
17 Optical filter array
18 Microlens array
19 Wiring layer
20 Photoelectric conversion unit
21 Trench portion
22 Optical filter
22a Wire grid polarizer
22b Plasmon filter
22c GMR filter
22d FP filter
23 Metal structure
24 Strip-shaped conductor
25 Outer peripheral portion
26 Slit portion
27 Microlens
28 Hole
29 Metal film
30 Diffraction grating
31 Strip-shaped conductor
32 Outer peripheral portion
33 Cladding layer
34 Core layer
35 Upper mirror layer
36 Lower mirror layer
37 Resonator layer
38 Photoelectric conversion unit group
39 Conductive portion
1000 Imaging device
1001 Lens group
1002 Solid-state imaging device
1003 DSP circuit
1004 Frame memory
1005 Monitor
1006 Memory
1007 Bus line

1. A photodetection device comprising:
a semiconductor substrate on which a plurality of photoelectric conversion units is formed; and
a plurality of optical filters disposed on a light incident surface side of the semiconductor substrate, wherein
each of the optical filters includes a metal structure including a metal material of a same kind, and
the photodetection device further comprises, between the metal structures, a slit portion spatially sectioning the metal structures.

2. The photodetection device according to claim 1, wherein
the optical filters are formed for the respective photoelectric conversion units, and
the slit portion is formed between some of the metal structures or between all of the metal structures.

3. The photodetection device according to claim 1, wherein
the optical filter is formed for each of photoelectric conversion unit groups each including two or more of the photoelectric conversion units, and
the slit portion is formed between some of the metal structures or between all of the metal structures.

4. The photodetection device according to claim 1, further comprising
a conductive portion that electrically connects the metal structures sectioned by the slit portion, wherein
the conductive portion includes a conductive material different from a metal material included in the metal structure.

5. The photodetection device according to claim 4, wherein
the conductive portion is disposed on a surface side of the metal structure on a side of the semiconductor substrate and is electrically connected to a surface of the metal structure on the semiconductor substrate side.

6. The photodetection device according to claim 4, wherein
the conductive portion is disposed in the slit portion and is electrically connected to a surface of the metal structure on the slit portion side.

7. The photodetection device according to claim 1, wherein
a light shielding portion that is disposed in the slit portion and blocks transmission of light in the slit portion.

8. The photodetection device according to claim 1, comprising
a light-shielding film disposed between the semiconductor substrate and the metal structures and formed along a gap between the photoelectric conversion units to cover a light incident surface side of the gap between the photoelectric conversion units, wherein
a slit width of the slit portion is smaller than a width of a portion of the light-shielding film extending along the gap between the photoelectric conversion units.

9. The photodetection device according to claim 1, wherein
a slit width of the slit portion is smaller than a wavelength of light incident on the slit portion.

10. The photodetection device according to claim 1, wherein
a shape of a portion of the slit portion extending along a gap between the photoelectric conversion units when viewed from a direction orthogonal to the light incident surface of the semiconductor substrate is linear.

11. The photodetection device according to claim 1, wherein
a shape of a portion of the slit portion extending along a gap between the photoelectric conversion units when viewed from a direction orthogonal to the light incident surface of the semiconductor substrate is a shape including a portion having a slit width different from a surrounding part.

12. The photodetection device according to claim 1, wherein
the optical filter is a wire grid polarizer.

13. The photodetection device according to claim 1, wherein
the optical filter is a plasmon filter.

14. The photodetection device according to claim 1, wherein
the optical filter is a guided mode resonance (GMR) filter.

15. The photodetection device according to claim 1, wherein
the optical filter is a Fabry-Perot (FP) filter.

16. An electronic device comprising
a photodetection device including: a semiconductor substrate on which a plurality of photoelectric conversion units is formed; and a plurality of optical filters disposed on a light incident surface side of the semiconductor substrate, wherein each of the optical filters includes a metal structure including a metal material of a same kind, and the photodetection device further comprises, between the metal structures, a slit portion spatially sectioning the metal structures.
